(19) United States
(12) Patent Application Publication
(10) Pub. No.: US 2012/0103668 A1
(43) Pub. Date: May 3, 2012

(54) Chip Package

(75) Inventor: Chung Hsing TZU, Taipei County (TW)

(73) Assignee: Great Team Backend Foundry, Inc., British Virgin Islands (GB)

(21) Appl. No.: 13/282,484

(22) Filed: Oct. 27, 2011

Related U.S. Application Data
(60) Provisional application No. 61/407,472, filed on Oct. 28, 2010.

(51) Int. Cl. H05K 1/09

(52) U.S. Cl. 174/257

(57) ABSTRACT

A chip package includes a conductive connection block connected to the conductive layer coated on the base and the two ends of the gold wire are respectively connected to the chip and the connection block. The connection block prevents lamination during packaging and ensures that the gold wire is firmly connected to the chip and the connection block.

### FIELD OF THE INVENTION

The present invention relates to a chip package, and more particularly, to a chip base with gold lines connected between connection blocks on the conductive later so as to prevent delamination.

### BACKGROUND OF THE INVENTION

A conventional chip package is shown in FIGS. 1 and 2 and generally includes a chip base 1, a chip 4, supports 6 and gold wires 5, wherein the base 1 is coated with a conductive copper layer 2 and the base 1 is connected to the chip 4 by using an adherent agent 3. The supports 6 each have the conductive copper layer 7. The gold wires 5 make the chip 4, the base 1 and the supports 6 to the electrically connected to each other. However, there may have impurities in the conductive copper layer 2 or the adherent agent overflows and is located on the conductive copper layer 2, so that when the end 51 of the gold wire 5 is soldered to the base 1, the gold wires 5 are located on the impurities or the adherent agent. When packaging, delamination 8 is happened on the surface of the base 1 and the end 51 of the gold wire 5 is separated from the conductive copper layer 2 which is supposed to be electrically connected with the gold wire 5. In other words, the connection between the end 51 of the gold wire 5 and the conductive copper layer 2 is not well established and the signals cannot be transferred via the connection. This increases the defect rate and the manufacturing cost.

The present invention intends to provide blocks located on the conductive layer of the chip base so as to improve the shortcoming of delamination.

### SUMMARY OF THE INVENTION

The present invention relates to a chip package and comprises a base having a conductive layer coated thereon and a chip is connected to the base by adherent agent. A connection block is connected to the conductive layer on the base and electrically connected with the base. A gold wire has two ends thereof respectively connected to the chip and the connection block.

The primary object of the present invention is to provide a chip package by connecting a connection block on the conductive layer of the base before the gold wire is connected to the chip and the base so as to reduce the defect rate and manufacturing cost.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view of the conventional chip package;

FIG. 2 shows the delamination of the conventional chip package;

FIG. 3 is a cross sectional view of the chip package of the present invention, and

FIG. 4 is a cross sectional view of another embodiment of the chip package of the present invention.

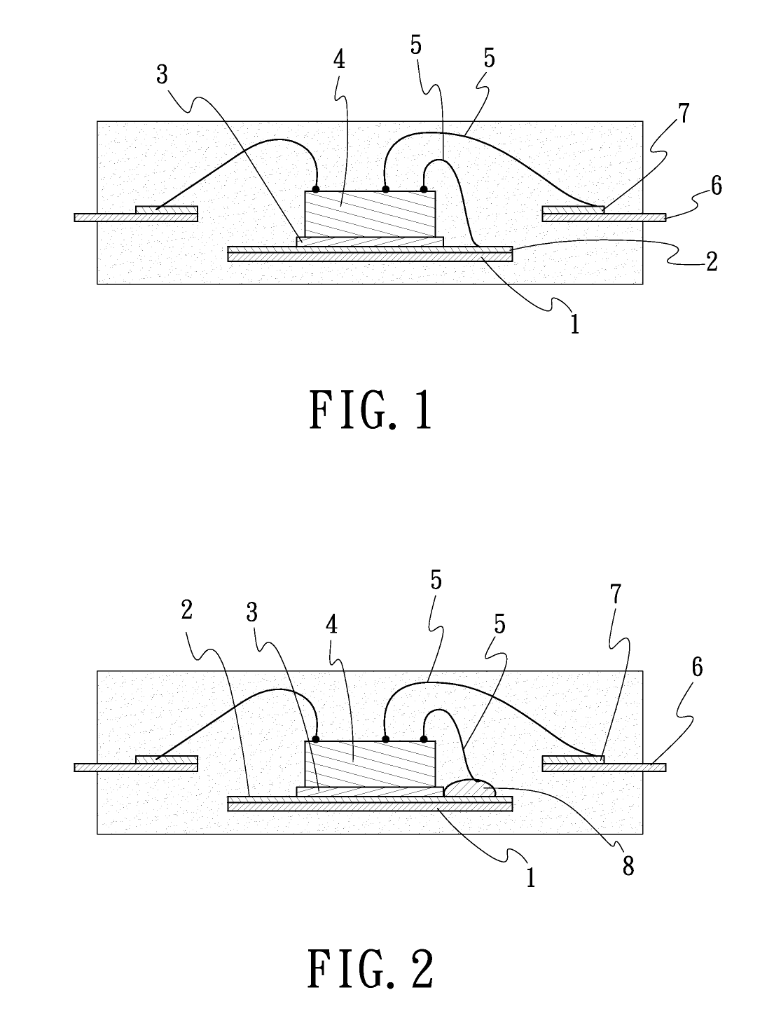

### DETAILED DESCRIPTION OF THE PREFERRED EMBODIMENT

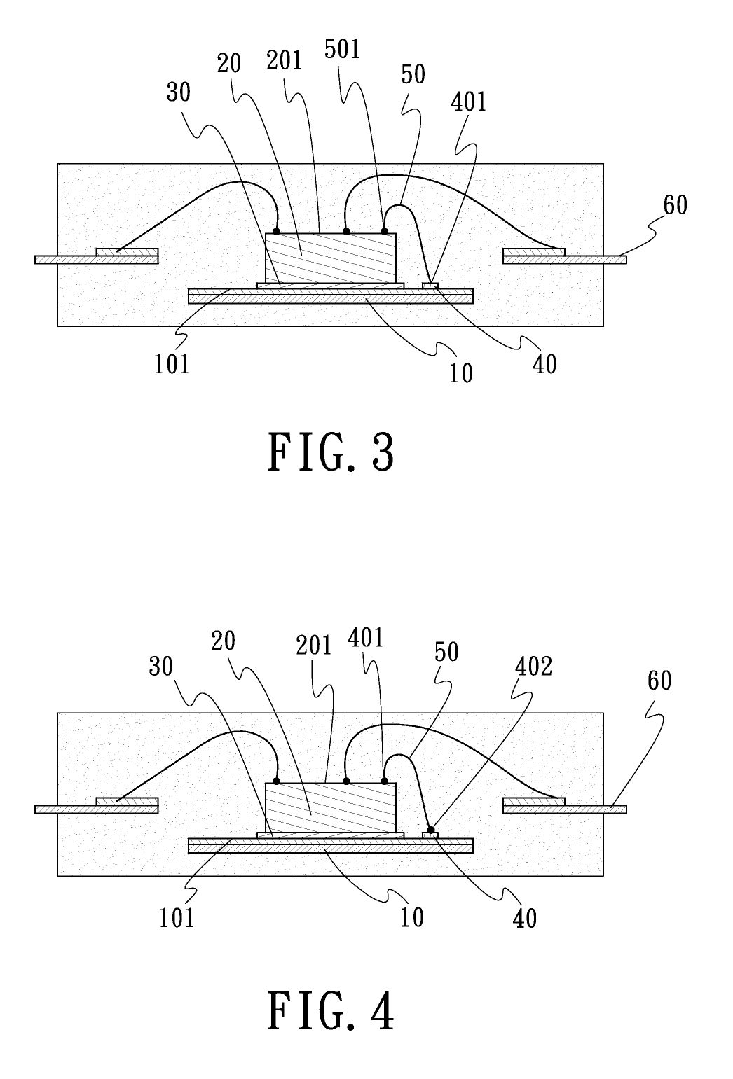

Referring to FIG. 3, the chip package of the present invention comprises a base 10 and a conductive layer 101 is coated on the base 10 by using adherent agent 30. A chip 20 is fixed to the base 10, wherein the conductive layer 101 is made by conductive metallic material which is gold, copper or aluminum.

The conductive layer 101 is located on the base 10 and a connection block 40 is connected to the conductive layer 101 on the base 10 by of ultrasonic oscillation in clean rooms so as to prevent impurities from being introduced between the base 10 and the connection block 40. The connection for connecting the connection block 40 to the base 10 is made prior the connection between the chip 20 and the base 10. By this way, the adherent agent can also be avoided from being introduced between the base 10 and the connection block 40. The connection block 40 is made by conductive metallic material which is gold, copper or aluminum.

When the connection block 40 and the chip 20 are respectively connected to the base 10, the gold wire is connected to the soldering needle (not shown) and a gold ball 501 is soldered to the top 201 of the chip 20, and then extends the gold wire 50 and connect the gold wire 50 to the top 401 of the connection block 40 by soldering. Therefore, the chip 20 is electrically connected to the base 10. The gold wire 50 is then used again to connect the chip 20 to the support 60. After the chip 20 is completely connected to the base 10, the packaging process can be started.

Due to the volume and the height of the connection block 40, when the chip 20 is connected to the base 10 by using the adherent agent 30, even if some of the adherent agent 30 overflows, the adherent agent 30 does not reach the top 401 of the connection block 40 where the gold wire 50 is to be soldered. Therefore, the delamination during packaging can be avoided and the defect rate can be reduced.

As shown in FIG. 4 which shows another embodiment of the present invention and which improves the connection between the gold wire 50 and the top 401 of the connection block 40. A gold ball 50 is formed on the top 401 of the connection block 40 before the gold wire 50 is soldered. The gold wire 50 forms a gold ball 501 on the top of the 201 of the chip 20 and the gold wire 50 is extended and connected to the top 401 of the connection block 40 by directly connecting the gold wire 50 to the gold ball 402 on the top 401 of the connection block 40. By this way, the gold wire 50 is firmly connected to the connection block 40 so as to reduce the defect rate.

While we have shown and described the embodiment in accordance with the present invention, it should be clear to those skilled in the art that further embodiments may be made without departing from the scope of the present invention.

What is claimed is:

1. A chip package comprising:
a base having a conductive layer coated thereon;
a chip connected to the base by adherent agent;
a connection block connected to the conductive layer on the base and being electrically connected with the base, and
a gold wire having two ends thereof respectively connected to the chip and the connection block.

2. The chip package as claimed in claim 1, wherein the conductive layer is made by conductive metallic material which is gold, copper or aluminum.

3. The chip package as claimed in claim 1, wherein the connection block is made by conductive metallic material which is gold, copper or aluminum.

4. The chip package as claimed in claim 1, wherein the connection block is connected to the base by way of ultrasonic oscillation in clean rooms.

5. The chip package as claimed in claim 1, wherein the connection lock has a gold ball on a top thereof so as to connect the gold wire with the connection block.
